(19) United States
(12) Patent Application Publication
(10) Pub. No.: US 2025/0311503 A1
(43) Pub. Date: Oct. 2, 2025

(54) DISPLAY PANEL AND DISPLAY DEVICE

(71) Applicant: Tianma Advanced Display Technology Institute (Xiamen) Co., Ltd., Xiamen (CN)

(72) Inventors: Zhenyu JIA, Xiamen (CN); Bo YANG, Xiamen (CN); Kerui XI, Xiamen (CN); Tianyi WU, Xiamen (CN); Yingteng ZHAI, Xiamen (CN); Fanqing MENG, Xiamen (CN); Wei CHENG, Xiamen (CN)

(21) Appl. No.: 19/237,040

(22) Filed: Jun. 13, 2025

(30) Foreign Application Priority Data
Nov. 1, 2024 (CN) 202411554809.9

(51) Int. Cl. H10H 29/39; H10H 29/49

(52) U.S. Cl. CPC H10H 29/39; H10H 29/49

(57) ABSTRACT

Provided are a display panel and a display device. In the display panel, a first metal layer has slots provided with electrode connection lines. The electrode connection lines respectively have a first end connected to a sub-pixel and a second end connected to a pixel circuit. The electrode connection lines in a connection-line group include a first connection line and a second connection line, which are located in different slots. In a first direction, first line segments of the first and the second connection lines are located on two sides of a pixel. In at least one connection-line group, the first ends of the first and the second connection lines are staggered in the first direction. The present disclosure can enhance the performance reliability of the display panel.

### CROSS-REFERENCE TO RELATED APPLICATIONS

The present application claims priority to Chinese Patent Application No. 202411554809.9, filed on Nov. 1, 2024, the content of which is incorporated herein by reference in its entirety.

### TECHNICAL FIELD

The present disclosure relates to the field of display technologies, and in particular, to a display panel and a display device.

### BACKGROUND

Light-emitting diode (LED) is a commonly used light-emitting device, which is currently widely applied in fields such as lighting and display. With the development of display technologies, display products using Mini LEDs or Micro LEDs as display pixels have emerged. In bezelless display products, pixel circuits are retracted inward, connection lines are provided to connect the pixel circuits and sub-pixels, and the connection lines are disposed within slots of a large-area metal, which ensures both the electrical connection between the pixel circuits and sub-pixels and the integrity of the large-area metal. However, there is a problem in current products where the metal burns out due to local heating, which affects the performance reliability of the products.

### SUMMARY

Embodiments of the present disclosure provide a display panel and a display device to solve the technical problem of enhancing the performance reliability of products.

In a first aspect, an embodiment of the present disclosure provides a display panel including a first metal layer, a plurality of sub-pixels, and a plurality of pixel circuits. At least two sub-pixels arranged along a first direction form a pixel; the first metal layer has slots, in which electrode connection lines are disposed, and the electrode connection lines and the first metal layer are located in a same layer. The electrode connection lines respectively have a first end connected to one of the sub-pixels, a second end connected to one of the pixel circuits, and a first line segment extending along a second direction, the first end and the second end are located on both sides of the first line segment in the second direction, and the second direction intersects the first direction. The electrode connection lines connected to the sub-pixels in a same pixel form a connection-line group. The electrode connection lines in the connection-line group include a first connection line and a second connection line, and the first connection line and the second connection line are located in different slots. In the first direction, the first line segment of the first connection line and the first line segment of the second connection line are located on both sides of the pixel. In at least one connection-line group, the first end of the first connection line and the first end of the second connection line are staggered in the first direction.

In a second aspect, based on the same inventive concept, an embodiment of the present disclosure further provide a display device including a display panel. The display panel includes a first metal layer, a plurality of sub-pixels, and a plurality of pixel circuits. At least two sub-pixels arranged along a first direction form a pixel; the first metal layer has slots provided with electrode connection lines, and the electrode connection lines and the first metal layer are located in a same layer; the electrode connection lines respectively include a first end connected to one of the sub-pixels, a second end connected to one of the pixel circuits, and a first line segment extending along a second direction, the first end and the second end are located on both sides of the first line segment in the second direction, and the second direction intersects the first direction. The electrode connection lines connected to the sub-pixels in a same pixel form a connection-line group; the electrode connection lines in the connection-line group include a first connection line and a second connection line, and the first connection line and the second connection line are located in different slots; and in the first direction, the first line segment of the first connection line and the first line segment of the second connection line are located on both sides of the pixel. In at least one connection-line group, the first end of the first connection line and the first end of the second connection line are staggered in the first direction.

### BRIEF DESCRIPTION OF DRAWINGS

In order to illustrate the technical solutions in the embodiments of the present disclosure or in the related art more clearly, the following briefly introduces the drawings required to be used in the description of the embodiments or the related art. Apparently, the drawings in the following description are some embodiments of the present disclosure. For those of skill in the art, other drawings can be obtained without creative efforts.

FIG. 1A is a schematic diagram of a display panel provided by an embodiment of the present disclosure;

FIG. 1B is a partial top-view at a position of a region Q in FIG. 1A;

FIG. 1C is a schematic diagram of a pixel circuit provided by an embodiment of the present disclosure;

FIG. 1D is a schematic diagram of another pixel circuit provided by an embodiment of the present disclosure;

FIG. 2 is a partial schematic diagram of another display panel provided by an embodiment of the present disclosure;

FIG. 3 is a partial schematic diagram of another display panel provided by an embodiment of the present disclosure;

FIG. 4 is a partial schematic diagram of another display panel provided by an embodiment of the present disclosure;

FIG. 5 is a partial schematic diagram of another display panel provided by an embodiment of the present disclosure;

FIG. 6 is a partial schematic diagram of another display panel provided by an embodiment of the present disclosure;

FIG. 7 is a schematic diagram of a film-layer structure of another display panel provided by an embodiment of the present disclosure;

FIG. 8 is a partial schematic diagram of another display panel provided by an embodiment of the present disclosure;

FIG. 9 is a partial schematic diagram of another display panel provided by an embodiment of the present disclosure;

FIG. 10 is a simplified schematic diagram of another display panel provided by an embodiment of the present disclosure;

FIG. 11A is a partial schematic diagram of another display panel provided by an embodiment of the present disclosure;

FIG. 11B is a schematic diagram of another display panel provided by an embodiment of the present disclosure;

FIG. 12 is a schematic diagram of another display panel provided by an embodiment of the present disclosure;

FIG. 13 is a schematic diagram of another display panel provided by an embodiment of the present disclosure;

FIG. 14 is a partial schematic diagram of another display panel provided by an embodiment of the present disclosure;

FIG. 15 is a partial simplified schematic diagram of another display panel provided by an embodiment of the present disclosure;

FIG. 16 is a partial schematic diagram of another display panel provided by an embodiment of the present disclosure;

FIG. 17 is a partial schematic diagram of another display panel provided by an embodiment of the present disclosure; and

FIG. 18 is a schematic diagram of a display device provided by an embodiment of the present disclosure.

### DESCRIPTION OF EXAMPLES

To make the objectives, technical solutions, and advantages of the embodiments of the present disclosure clearer, the technical solutions of the embodiments of the present disclosure will be clearly and completely described in conjunction with the accompanying drawings. Apparently, the described embodiments are part of the embodiments of the present disclosure, not all of them. Based on the embodiments of the present disclosure, all other embodiments obtained by those of ordinary skill in the art without creative efforts shall fall within the protection scope of the present disclosure.

The terms used in the embodiments of the present disclosure are only for the purpose of describing specific embodiments and are not intended to limit the present disclosure. The singular forms “a/an”, “said”, and “the” used in the embodiments of the present disclosure and the appended claims are also intended to include the plural forms, unless the context clearly indicates otherwise.

Aiming at the problem in current products where the metal burns out due to local heating, relevant research has been carried out. Through research, it has been found that the current structure of making slots on the metal and disposing connection lines in the slots splits the large-area metal. A weak region for electrical-signal transmission is formed at the junction of the split regions. When a current is larger, it is easy to cause heat generation and the risk of burnout, affecting the performance reliability of the products.

To solve the problem in the related art, an embodiment of the present disclosure provides a display panel. Slots are provided on a first metal layer, and electrode connection lines are disposed in the slots, a first end of the electrode connection line is connected to a sub-pixel, and a second end of the electrode connection line is connected to a pixel circuit. The electrode connection line is used to connect the pixel circuit and the sub-pixel that are arranged in a staggered manner. A first connection line and a second connection line in a connection-line group connected to a same pixel are respectively disposed on both sides of the pixel in a first direction, and the first end of the first connection line and the first end of the second connection line are staggered in the first direction. Thereby, a linear distance between the first end of the first connection line and the first end of the second connection line can be increased, improving the heat-generation problem at this position, reducing the risk of burnout, and enhancing the performance reliability.

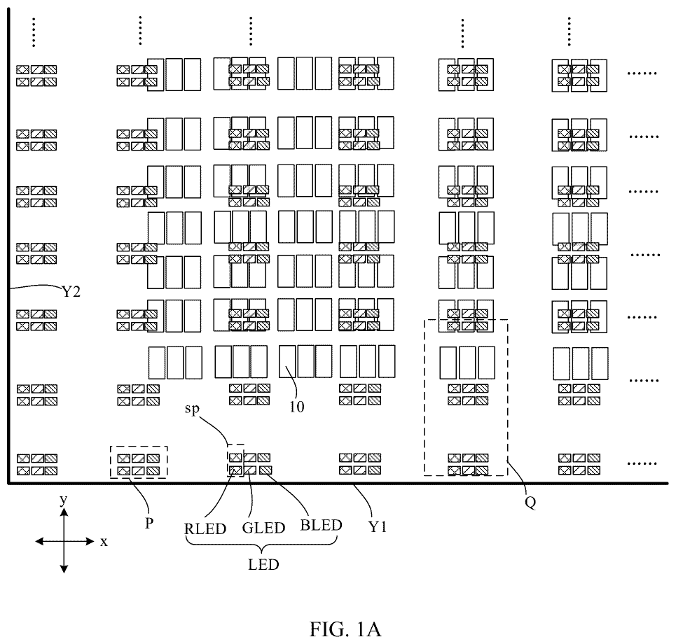

FIG. 1A is a schematic diagram of a display panel provided by an embodiment of the present disclosure, and FIG. 1B is a partial top-view of the location of a region Q in FIG. 1A. As shown in FIG. 1A, the display panel includes a plurality of sub-pixels sp and a plurality of pixel circuits 10. At least two sub-pixels sp arranged along the first direction x form a pixel P. In FIG. 1A, it is exemplified that three sub-pixels sp form a pixel P. The three sub-pixels sp include a red sub-pixel, a green sub-pixel, and a blue sub-pixel. The sub-pixel sp includes a light-emitting device. In FIG. 1A, it is exemplified that the sub-pixel sp includes a light-emitting diode LED. The red sub-pixel includes a red light-emitting diode RLED, the green sub-pixel includes a green light-emitting diode GLED, and the blue sub-pixel includes a blue light-emitting diode BLED. FIG. 1A illustrates that there is a redundant design at the position of the sub-pixel sp. For example, one of the two LEDs included in the sub-pixel sp is a redundant design. One LED is first fixed at the position of the sub-pixel sp, and when it is detected that this LED has a defect and cannot emit light, another LED of the same color is fixed for repair. The previously fixed LED remains in its original position, so that one sub-pixel sp has two LEDs therein. In some other embodiments, one sub-pixel sp includes one LED. During manufacturing, one LED is first fixed at the position of one sub-pixel sp, and when it is detected that this LED has a defect and cannot emit light, this defective LED is removed, and then another LED is fixed in situ for repair. As such, the final sub-pixel sp includes one LED.

As shown in FIG. 1B, the display panel includes a first metal layer M1. The first metal layer M1 has slots 20, and electrode connection lines 30 are arranged in the slots 20. The electrode connection lines 30 and the first metal layer M1 are on a same layer. A first end 61 of the electrode connection line 30 is connected to the sub-pixel sp, and the second end 62 is connected to the pixel circuit 10. For example, the first end 61 of the electrode connection line 30 is connected to the sub-pixel sp through a first electrode 51, and the second end 62 is connected to the pixel circuit 10 through a connection lead 53. The first electrode 51 can be an anode, and the first electrode 51 and the first metal layer M1 are located on different layers. FIG. 1B illustrates a first via-hole V1 through which the electrode connection line 30 is connected to the first electrode 51. The electrode connection line 30 includes a first line segment 30a extending along a second direction y. The first end 61 and the second end 62 are on both sides of the first line segment 30a in the second direction y, and the second direction y intersects the first direction x. The term “end” defined in the embodiments of the present disclosure refers to a site on the electrode connection line 30 that is connected to a via-hole, and the end has a certain area. As can be seen from the top-view in FIG. 1B, the first end 61 overlaps with the first via-hole V1. In fact, the second end 62 and the connection lead 53 also need to be connected to each other through a via-hole, but the via-hole through which the second end 62 and the connection lead 53 are connected to each other is not shown in FIG. 1B.

In the present disclosure, the pixel circuit 10 is only shown in a simplified manner. The pixel circuit 10 can be a conventional 7T1C pixel circuit, that is, it includes seven transistors and one storage capacitor. The pixel circuit 10 can also be a pixel circuit of Pulse Amplitude Modulation (PAM) circuit+Pulse Width Modulation (PWM) circuit.

FIG. 1C is a schematic diagram of a pixel circuit provided by an embodiment of the present disclosure, showing a 7T1C-structured pixel circuit. As shown in FIG. 1C, the pixel circuit includes a driving transistor Tm, a data-writing transistor T1, a gate-reset transistor T3, a threshold-compensation transistor T4, an electrode-reset transistor T7, a first light-emitting control transistor T5, a second light-emitting control transistor T6, and a storage capacitor Cst. A gate of the data-writing transistor T1 and a gate of the threshold-compensation transistor T4 are connected to a first scan signal S1. A gate of the gate-reset transistor T3 is connected to a second scan signal S2. A gate of the first light-emitting control transistor T5 and a gate of the second light-emitting control transistor T6 are connected to a light-emitting control signal Emit. In addition, the gate-reset transistor T3 and the electrode-reset transistor T7 are respectively connected to a reset signal Ref. The driving transistor Tm is connected in series between the first light-emitting control transistor T5 and the second light-emitting control transistor T6. One electrode of the first light-emitting control transistor T5 is connected to a first power-supply voltage VDD, and a LED has one electrode connected to the second light-emitting control transistor T6 and the other electrode connected to the second power-supply voltage VEE.

FIG. 1D is a schematic diagram of another pixel circuit provided by an embodiment of the present disclosure. As shown in FIG. 1D, the pixel circuit includes a first driving circuit 001 and a second driving circuit 002. The first driving circuit 001 is configured to control a duration of a driving current provided to a light-emitting device LED based on a first data voltage PWM-data. The second driving circuit 002 is configured to control an amplitude of the driving current provided to the light-emitting device LED based on a second data voltage PAM-data.

The first driving circuit 001 includes a first driving transistor T1, a first gate-reset transistor T2, a first data-writing transistor T3, a first compensation transistor T4, a first control transistor T6, a second control transistor T5, and a first capacitor C1. The first capacitor C1 is a storage capacitor in the first driving circuit 001. The second control transistor T5 is connected between a first power-supply voltage PWM-vdd and a first electrode of the first driving transistor T1. The first control transistor T6 is connected between a second electrode of the first driving transistor T1 and a first node N1. The first data-writing transistor T3 is connected to a first electrode of the first driving transistor T1. The first compensation transistor T4 is connected to the second electrode and a gate of the first driving transistor T1. The first gate-reset transistor T2 is connected to the gate of the first driving transistor T1. A first plate of the first capacitor C1 is connected to the gate of the first driving transistor T1, and a second plate of the first capacitor C1 is connected to a sweep signal SWEEP. A gate of the first gate-reset transistor T2 is connected to a third scan signal PWM-S1, and a gate of the first data-writing transistor T3 and a gate of the first compensation transistor T4 are connected to a fourth scan signal PWM-S2. A gate of the first control transistor T6 and a gate of the second control transistor T5 are connected to a first light-emitting control signal PWM-EM.

The second driving circuit 002 includes a second driving transistor T7, a second gate-reset transistor T8, a second data-writing transistor T9, a second compensation transistor T10, a third control transistor T11, a fourth control transistor T12, an electrode-reset transistor T13, and a second capacitor C2. The third control transistor T11 is connected between a second power-supply voltage PAM-vdd and a first electrode of the second driving transistor T7. The fourth control transistor T12 is connected between a second electrode of the second driving transistor T7 and the light-emitting device LED. The second driving transistor T7 is configured to generate the driving current under the control of a voltage at its gate. The gate of the second driving transistor T7 is connected to the first node N1. The second data-writing transistor T9 is connected to the first electrode of the second driving transistor T7. The second compensation transistor T10 is connected to the second electrode and the gate of the second driving transistor T7. The second gate-reset transistor T8 is connected to the gate of the second driving transistor T7. The electrode-reset transistor T13 is connected to a first electrode of the light-emitting device LED. The fourth control transistor T12 is also connected to the first electrode of the light-emitting device LED, and a second electrode of the light-emitting device LED is connected to a third power-supply voltage VEE. The gate of the second gate-reset transistor T8 is connected to a first scan signal PAM-S1. A gate of the second data-writing transistor T9, a gate of the second compensation transistor T10, and a gate of the electrode-reset transistor T13 are connected to a second scan signal PAM-S2. A gate of the third control transistor T11 and a gate of the fourth control transistor T12 are connected to a second light-emitting control signal PAM-EM.

It can be seen from FIG. 1B that the pixel circuit 10 and the sub-pixel sp connected by the electrode connection line 30 are arranged in a staggered manner in the first direction x. That is, the pixel circuit 10 and the sub-pixel sp are separated by a larger distance in the second direction y. The embodiment of the present disclosure can be applied to the solution in which the pixel circuit 10 is retracted inwards in the second direction y relative to the edge of the display panel. The pixel circuit 10 is shifted toward the inside of the display panel, which can narrow the bezel of the display panel.

The electrode connection lines 30 connected to the sub-pixels sp in a same pixel P form a connection-line group 30Z. The electrode connection lines 30 in the connection-line group 30Z include a first connection line 31 and a second connection line 32, which are located in different slots 20. In the first direction x, the first line segment 30a of the first connection line 31 and the first line segment 30a of the second connection line 32 are on both sides of the pixel P. That is, the first connection line 31 and the second connection line 32 are routed on the left and right sides of the pixel P respectively. As can be seen from the position of the region Q1 in FIG. 1B, in at least one connection-line group 30Z, the first end 61 of the first connection line 31 and the first end 61 of the second connection line 32 are staggered in the first direction x. The staggering of the two first ends 61 of the two connection lines in the first direction x means that the two first ends are not aligned in the first direction x, or there is a certain distance between the two first ends 61 in the second direction y.

In the embodiments of the present disclosure, the first metal layer M1 has slots 20, electrode connection lines 30 are disposed in the slots 20, the electrode connection lines 30 and the first metal layer M1 are on a same layer, the first metal layer M1 can be used to transmit voltage signals, and designing it as a large-area metal layer in the display panel can improve the in-plane signal uniformity. The electrode connection line 30 is used to connect the pixel circuit 10 and the sub-pixel sp. Since the electrode connection line 30 is made in the slot 20 of the first metal layer M1, in order to ensure the integrity of the first metal layer M1, the slot 20 of an appropriate size will be made according to the size of the electrode connection line 30, and the electrode connection line 30 and the slot 20 where the electrode connection line 30 is located are equivalent to splitting the first metal layer M1. In a connection-line group 30Z, the first line segment 30a of the first connection line 31 and the first line segment 30a of the second connection line 32 are respectively located on both sides of the pixel P in the first direction x, which is equivalent that the first connection line 31 and the second connection line 32 respectively split the first metal layer M1 in the first direction x. It is easy to form a weak region for electrical-signal transmission at the junction of the split regions. In the embodiments of the present disclosure, by setting that the first end 61 of the first connection line 31 and the first end 61 of the second connection line 32 in at least one connection-line group 30Z are staggered in the first direction x, the linear distance between the two first ends 61 can be increased, correspondingly, the linear distance between the slots 20 where the two first ends 61 are located is also increased, that is, the width of the solid-structure of the first metal layer M1 between the two first ends 61 is increased, thereby improving the electrical-signal transmission ability, alleviating the heat-generation problem caused by a larger current in the regions split by the first connection line 31 and the second connection line 32, reducing the risk of burnout of the region between the two first ends 61, and thus enhancing the performance reliability of the display panel.

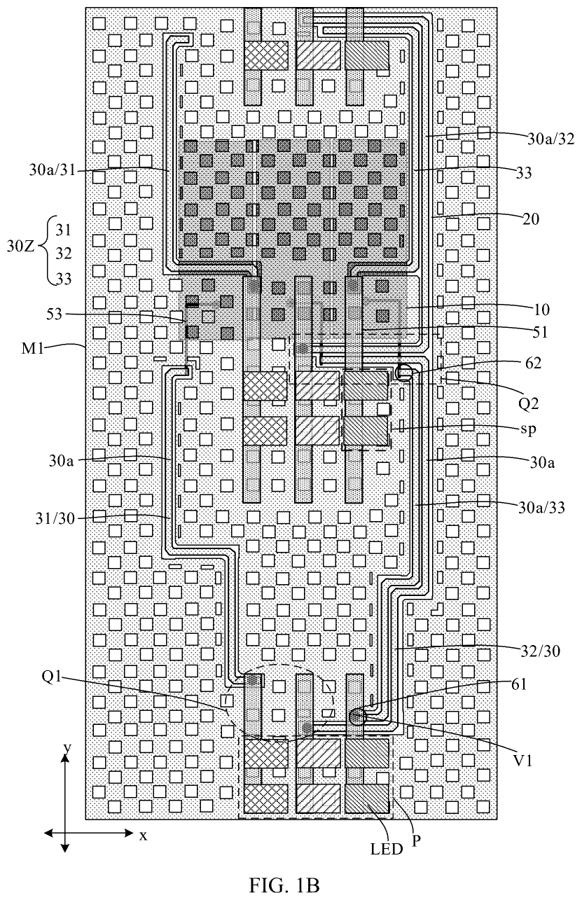

In some embodiments, FIG. 2 is a partial schematic diagram of another display panel provided by an embodiment of the present disclosure. FIG. 2 only illustrates a partial structure of the first metal layer M1. As shown in FIG. 2, the display panel includes a pixel region Z1, in which the pixels P (see the illustration in FIG. 1B) are located. A part of the first metal layer M1 located in the pixel region Z1 includes a plurality of first vent holes 41. In the pixel region Z1, the first vent holes 41 are arranged along the first direction x to form first vent-hole rows 41H. It can be seen that second vent holes 42 are arranged in the region outside the pixel region Z1 of the first metal layer M1. The vent holes penetrate the first metal layer M1 in a thickness direction, and the vent holes are equivalent to holes dug in the metal layer. The vent holes are used as gas-discharge channels during the manufacturing process, which can prevent the large-area first metal layer M1 from film-peeling due to the fact that the gas cannot be discharged. FIG. 2 illustrates two connection-line groups 30Z. From the first connection-line group 30Z counted from the top to bottom among the two connection-line groups 30Z, it can be seen that the first end 61 of the first connection line 31 and the first end 61 of the second connection line 32 are separated by at least one first vent-hole row 41H along the second direction y. The double-headed arrow in FIG. 2 illustrates the split region between the first end 61 of the first connection line 31 and the first end 61 of the second connection line 32 along the second direction y.

In the embodiments of the present disclosure, the pixels P are located in the pixel region Z1, and thus in the pixel P, the first electrodes 51 are also located in the pixel region Z1. In order to achieve the connections between the electrode connection lines 30 and the sub-pixels sp, each electrode connection line 30 needs to extend its first end 61 into the pixel region Z1 to be electrically connected to the first electrode 51. The part of the first metal layer M1 located in the pixel region Z1 includes the plurality of first vent holes 41, and the first end 61 of the first connection line 31 and the first end 61 of the second connection line 32 is set to be separated by at least one first vent-hole row 41H in the second direction y, which can increase the linear distance between the two first ends 61 of the first connection line 31 and the second connection line 32, and correspondingly increase the linear distance between the slots 20 where the two ends 61 are located, thereby improving the electrical-signal transmission ability, alleviating the heat-generation problem in the regions split by the first connection line 31 and the second connection line 32, reducing the risk of burnout at the opposite positions of the two first ends 61, and thus enhancing the performance reliability of the display panel.

In some embodiments, in the pixel region Z1, the first vent holes 41 are arranged along the first direction x to form first vent-hole rows 41H, and in the second direction y, a distance between two adjacent first vent-hole rows 41H is d1. FIG. 2 illustrates two connection-line groups 30Z. From the second connection-line group 30Z counted from the top to bottom among the two connection-line groups 30Z, it can be seen that a minimum distance along the second direction y between the slot where the first connection line 31 is located and the slot where the second connection line 32 is located is d2, where d2≥d1. The slots 20 are made on the first metal layer M1, and the electrode connection lines 30 are located in the slots 20. Then, a certain process distance is also required between the electrode connection lines 30 and the side walls of the slots 20 to ensure the insulation between the electrode connection lines 30 and the first metal layer M1. In the embodiments of the present disclosure, the end of the slot where the first connection line 31 is located and the end of the slot where the second connection line 32 is located are staggered in the first direction x, and it is set that d2≥d1, so that the first end 61 of the first connection line 31 and the first end 61 of the second connection line 32 are staggered in the first direction x and the linear distance between them is increased, thereby improving the electrical-signal transmission ability, alleviating the heat-generation problem caused by a larger current in the regions split by the first connection line 31 and the second connection line 32, and reducing the risk of burnout of the region between the two first ends 61.

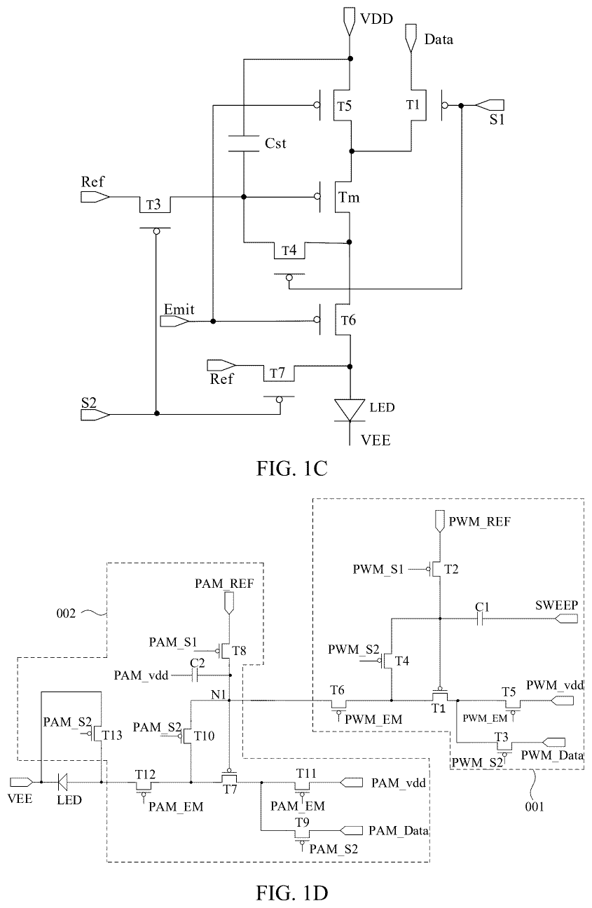

In some other embodiments, FIG. 3 is a partial schematic diagram of another display panel provided by an embodiment of the present disclosure. FIG. 3 illustrates a partial region of the first metal layer M1. As shown in FIG. 3, the display panel includes a pixel region Z1, and a part of the first metal layer M1 located in the pixel region Z1 includes a plurality of first vent holes 41. In the pixel region Z1, the first vent holes 41 are arranged along the first direction x to form first vent-hole rows 41H. In at least one connection-line group 30Z, the first end 61 of the first connection line 31 overlaps with one first vent-hole row 41H along the first direction x, and the first end 61 of the second connection line 32 overlaps with another one first vent-hole row 41H along the first direction x. The first vent-hole row 41H overlapping with the first connection line 31 is adjacent to the first vent-hole row 41H overlapping with the second connection line 32. In other words, the two first vent-hole rows 41H that respectively overlap with the first end 61 of the first connection line 31 and the first end 61 of the second connection line 32 in the first direction x are two adjacent first vent-hole rows 41H. In the embodiment of FIG. 3, there are two connection-line groups 30Z counted from top to bottom, and it can be seen that in each of the two connection-line groups 30Z, the first vent-hole row 41H overlapping with the first end 61 of the first connection line 31 in the first direction x and the first vent-hole row 41H overlapping with the first end 61 of the second connection line 32 in the first direction x are set to be adjacent first vent-hole rows 41H. Using the design of the embodiment of the present disclosure can increase the linear distance between the two first ends 61 of the first connection line 31 and the second connection line 32, thereby improving the electrical-signal transmission ability and alleviating the heat-generation problem caused by a larger current in the regions split by the first connection line 31 and the second connection line 32.

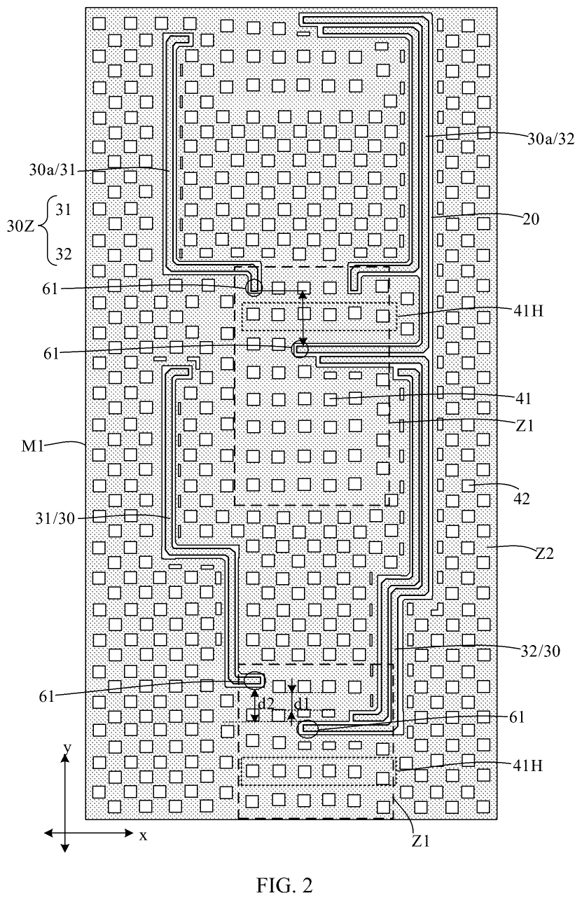

In some other embodiments, FIG. 4 is a partial schematic diagram of another display panel provided by an embodiment of the present disclosure. FIG. 4 illustrates a partial region of the first metal layer M1 and a first edge Y1 of the display panel extending along the first direction x. The position of the first edge Y1 can be understood in conjunction with FIG. 1A. As shown in FIG. 4, the first metal layer M1 includes a plurality of vent holes 40. The connection-line groups 30Z includes a first connection-line group 30Z1 and a second connection-line group 30Z2. A distance between the first connection-line group 30Z1 and the first edge Y1 is less than a distance between the second connection-line group 30Z2 and the first edge Y1. In the first connection-line group 30Z1, the first end 61 of the first connection line 31 and the first end 61 of the second connection line 32 are staggered in the first direction x, and a staggering distance along the second direction y between them is d3, and in the second connection-line group 30Z2, the first end 61 of the first connection line 31 and the first end 61 of the second connection line 32 are staggered in the first direction x, and a staggering distance along the second direction y between them is d4, where d4<d3. Compared with the second connection-line group 30Z2, the first connection-line group 30Z1 is closer to the first edge Y1. When the first metal layer M1 is used to transmit voltage signals, the power-supply source of the voltage signals is generally located at the edge of the first metal layer M1. For example, when the power-supply source of the first metal layer M1 is close to the first edge Y1, the first connection-line group 30Z1 is closer to the power-supply source than the second connection-line group 30Z2. The region between the first end 61 of the first connection line 31 and the first end 61 of the second connection line 32 in the first connection-line group 30Z1 is closer to the total current source of the power supply. Setting d3>d4 can relatively relieve the heat-generation problem caused by a larger current in the region between the two first ends 61 in the first connection-line group 30Z1 to a greater extent, thereby reducing the risk of burnout of the region between the two first ends 61 and enhancing the performance reliability of the display panel.

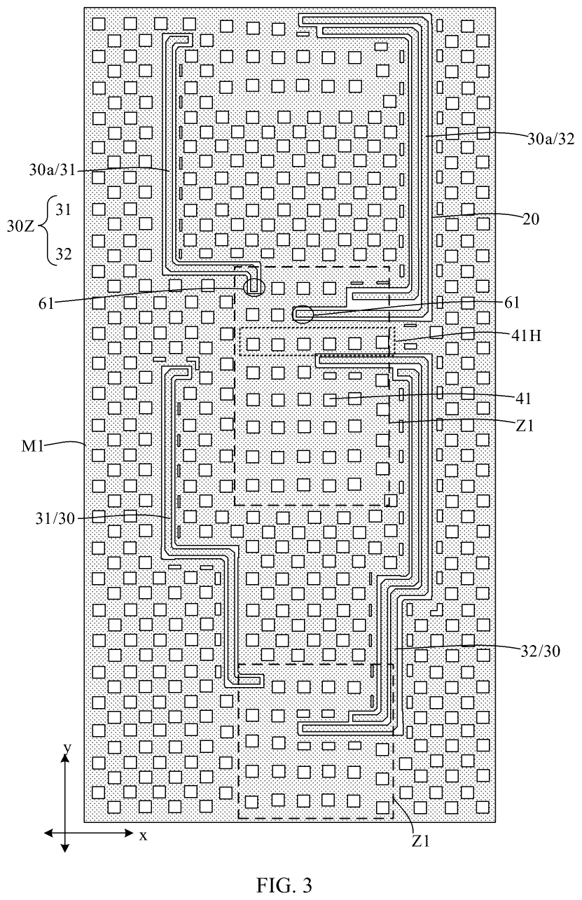

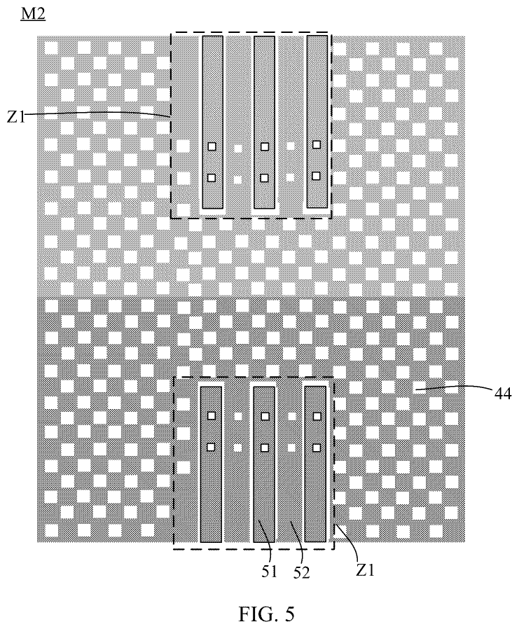

In some embodiments, FIG. 5 is a partial schematic diagram of another display panel provided by an embodiment of the present disclosure. As shown in FIG. 5, the display panel further includes a second metal layer M2. The second metal layer M2 includes first electrodes 51 and second electrodes 52. The first electrodes 51 are isolated from each other, and the second electrodes 52 are electrically connected to each other. Grooves are made on the second metal layer M2, and the first electrodes 51 are located in the grooves. Pixel regions Z1 are marked in FIG. 5, it can be seen that the first electrodes 51 and the second electrodes 52 are located in the pixel regions Z1. The first electrode 51 and the second electrode 52 are used to connect a sub-pixels sp. One of the first electrode 51 and the second electrode 52 is connected to the anode of a LED, and the other is connected to the cathode of the LED. The film layer of the second metal layer M2 is placed between the first metal layer M1 and the sub-pixels sp (can be seen from the illustration in FIG. 7). It can be seen from FIG. 5 that the second metal layer M2 includes a plurality of fourth vent holes 44. The fourth vent holes 44 are used as gas-discharge channels during the manufacturing process and can prevent the large-area second metal layer M2 from film-peeling due to the fact that the gas cannot be discharged.

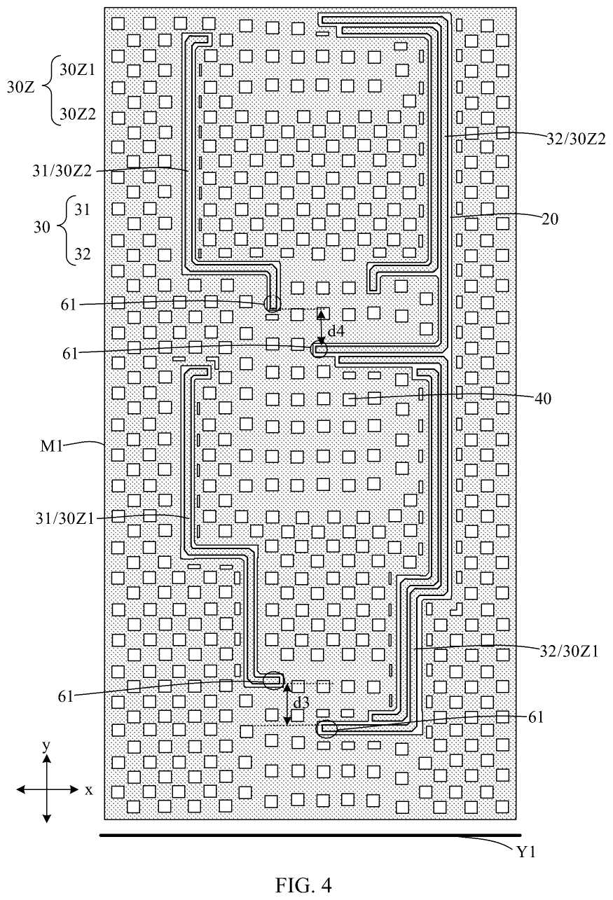

FIG. 6 is a partial schematic diagram of another display panel provided by an embodiment of the present disclosure. FIG. 6 illustrates an overlapping schematic diagram of the first metal layer M1 and the second metal layer M2. It can be seen that the electrode connection line 30 is electrically connected to the first electrode 51 through a first via-hole V1, and thus the electrode connection line 30 is connected to the sub-pixel sp (see the illustration in FIG. 1B) through the first electrode 51. The first electrode 51 includes a first side B1 and a second side B2 opposite to each other in the second direction y. Along the second direction y, a distance between the first end of the first connection line 31 and the first side B1 is d5, and a distance between the first end of the second connection line 32 and the first side B1 is d6, where d5≠d6. FIG. 6 takes d5<d6 as an example. The first end of the first connection line 31 and the first end of the second connection line 32 are not shown in FIG. 6, which can be understood in conjunction with FIG. 1B. The second end 62 of the first connection line 31 is marked in FIG. 6, to illustrate that in the second direction y, a distance between the first side B1 and the second end 62 is less than a distance between the second side B2 and the second end 62. In some other embodiments, in the second direction y, the distance between the first side B1 and the second end 62 is greater than the distance between the second side B2 and the second end 62, and d5≠d6. In this way, the first end of the first connection line 31 and the first end of the second connection line 32 are staggered in the first direction x.

During manufacturing, the first electrodes 51 in one pixel region Z1 are regularly disposed. For example, three first electrodes 51 are arranged along the first direction x, and the three first electrodes 51 have essentially the same size. In the embodiment of the present disclosure, setting d5≠d6 can make the first end of the first connection line 31 and the first end of the second connection line 32 staggered in the first direction x, which can increase the linear distance between the two first ends, alleviate the heat-generation problem caused by a larger current in the regions split by the first connection line 31 and the second connection line 32, reduce the risk of burnout of the region between the two first ends 61, and thus enhance the performance reliability of the display panel.

In some embodiments, FIG. 7 is a schematic diagram of a film-layer structure of another display panel provided by an embodiment of the present disclosure. As shown in FIG. 7, the display panel includes a substrate 00, a driving layer 01 located above the substrate 00, a first metal layer M1 and a second metal layer M2 located on one side of the driving layer 01 away from the substrate 00. It can be seen from FIG. 7 that the film layer of the second metal layer M2 is placed between the first metal layer M1 and the sub-pixels sp. A eutectic layer 015 is further disposed on one side of the second metal layer M2 away from the substrate 00. The electrodes of the light-emitting devices LED in the sub-pixels sp are connected to the electrodes in the second metal layer M2 through the eutectic layer 015. The driving layer 01 includes pixel circuits 10. A transistor TFT in the pixel circuit 10 is marked in FIG. 7. The driving layer 01 includes a semiconductor layer 011, a gate metal layer 012, an electrode metal layer 013, and a source-drain metal layer 014. An active layer of the transistor TFT is located in the semiconductor layer 011. A light-shielding layer 02 is further disposed between the semiconductor layer 011 and the substrate 00. Along a direction e perpendicular to the plane of the substrate 00, the light-shielding layer 02 overlaps with the active layer of the transistor TFT. The light-shielding layer 02 is used to light-shield the active layer of the transistor TFT on the side of the substrate 00 to prevent light from irradiating the active layer and thus affecting the performance of the transistor TFT. A gate of the transistor TFT is located in the gate metal layer 012. A first electrode plate of a storage capacitor is disposed in the electrode metal layer 013, and a second electrode plate of the storage capacitor is located in the gate metal layer 012. At least parts of the source and drain of the transistor TFT are disposed in the source-drain metal layer 014. The first metal layer M1 is located on one side of the second metal layer M2 close to the substrate 00, and the pixel circuits 10 are disposed between the first metal layer M1 and the substrate 00. The sub-pixels sp are disposed on one side of the second metal layer M2 away from the first metal layer M1. A positive-power-supply structure for transmitting a positive-power-supply signal can be disposed in the first metal layer M1, and a negative-power-supply structure for transmitting a negative-power-supply signal can be disposed in the second metal layer M2. Setting both the positive-power-supply structure and the negative-power-supply structure as large-area metal structures can reduce the voltage drop of the transmitted power-supply signal and improve the display uniformity. In addition, combined with the design of vent holes on the large-area metal, the gas generated during the manufacturing process of the display panel can be discharged through the vent holes, preventing the large-area metal from film-peeling.

In conjunction with the top-view of FIG. 1B, the relative position of the pixel circuit 10 and the electrode connection lines 30 is illustrated in FIG. 1B. In FIG. 1B, the pixel circuit 10 is only shown as a block diagram. It can be understood that in the embodiment of the present disclosure, the pixel circuit 10 includes the structure of the transistor TFT. In the embodiment of the present disclosure, it is set that along the direction perpendicular to the plane of the substrate, the electrode connection lines 30 do not overlap with the transistor TFT. Such a setting can avoid the influence of the slots 20 accommodating the electrode connection lines 30 on the transistor TFT, thereby avoiding the performance of the transistor TFT from being affected by light.

In some embodiments, as shown in FIG. 1B, the electrode connection lines 30 in the connection-line group 30Z further include a third connection line 33. The slot 20 where the third connection line 33 is located communicates with the slot 20 where the second connection line 32 is located, and in the first direction x, the first line segment 30a of the first connection line 31 and the first line segment 30a of the third connection line 33 are on both sides of the pixel P. It can be seen from FIG. 1B that in the first direction x, a distance between a first end 61 of the third connection line 33 and the first end 61 of the first connection line 31 is greater than a distance between the first end 61 of the second connection line 32 and the first end 61 of the first connection line 31. In at least one connection-line group 30Z, the first end 61 of the first connection line 31 and the first end 61 of the third connection line 33 are staggered in the first direction x, or the first end 61 of the first connection line 31 and the first end 61 of the third connection line 33 are aligned in the first direction x. FIG. 1B illustrates two first connection-line groups 30Z. In the first connection-line group 30Z counted from the top to bottom in FIG. 1B, the first end 61 of the first connection line 31 and the first end 61 of the third connection line 33 are basically aligned in the first direction x. In the second connection-line group 30Z counted from the top to bottom in FIG. 1B, the first end 61 of the first connection line 31 and the first end 61 of the third connection line 33 are staggered in the first direction x. It is understood that the alignment of the two first ends in the first direction x means that there is basically no misalignment in the first direction x, and the misalignment of the two first ends in the first direction x includes complete staggering and partial staggering in the first direction x. Setting one connection-line group 30Z to include three electrode connection lines 30 can match the design of one pixel P including three sub-pixels sp, realizing that each of the sub-pixels sp is electrically connected to a pixel circuit 10 through a corresponding electrode connection line 30. By setting the slot 20 where the third connection line 33 is located to communicate with the slot 20 where the second connection line 32 is located, the three electrode connection lines 30 are routed on the left and right sides of the pixel P, and the third connection line 33 and the second connection line 32 are located on the same side of the pixel P. Further, by designing the first end 61 of the third connection line 33 and the first end 61 of the second connection line 32 to correspond (align or stagger) to the first end 61 of the first connection line 31 in the first direction x, it is possible to improve the heat-generation problem caused by a larger current in the regions split by the three electrode connection lines 30 in the connection-line group 30Z, reduce the risk of burnout of the region between the two first ends 61, and thus enhance the performance reliability of the display panel.

In some embodiments, as shown in FIG. 1B, three sub-pixels sp arranged along the first direction x form a pixel P. In the pixel P, the sub-pixel sp connected to the first connection line 31, the sub-pixel sp connected to the second connection line 32, and the sub-pixel sp connected to the third connection line 33 are arranged in sequence. In one connection-line group 30Z, a distance between the first line segment 30a of the second connection line 32 and the first line segment 30a of the first connection line 31 is greater than a distance between the first line segment 30a of the third connection line 33 and the first line segment 30a of the first connection line 31. Such an arrangement can make the design of the slots 20 in the first metal layer M1 more convenient. It is understood that in conjunction with the position of the region Q2 in FIG. 1B, in order to save the number and area of the slots 20 and ensure the overall area of the non-slot region of the first metal layer M1, it is arranged that the slot 20 where the first end of the second connection line 32 in the previous connection-line group 30Z is located and the slots 20 where the second ends of the second connection line 32 and the third connection line 33 in the next connection-line group 30Z are located communicate. Assuming that the distance between the first line segment 30a of the second connection line 32 and the first line segment 30a of the first connection line 31 is less than the distance between the first line segment 30a of the third connection line 33 and the first line segment 30a of the first connection line 31, that is, the second connection line 32 is routed on the inner side of the third connection line 33 (the inner side and outer side are determined relative to the first connection line 31, and the side close to the first connection line 31 in the same connection-line group 30Z is the inner side, and the side far from the first connection line 31 is the outer side). Since the second connection line 32 needs to be connected to the middle one of the three pixel circuits 10, the left-side edge of the slot 20 in the region Q2 will form an alternately concave-convex shape, which is not conducive to the design of the slots 20 on the first metal layer M1. However, by using the design of the embodiments of the present disclosure, the left-hand edge of the slot 20 in the region Q2 generally forms a stepped shape, and the shape of the edge of the slots 20 change more smoothly, which is beneficial to making the slots 20 occupy less space. In addition, in the embodiments of the present disclosure, arranging the second connection line 32 outside the third connection line 33 can be more conducive to increasing the distance between the first end 61 of the first connection line 31 and the first end 61 of the second connection line 32, reducing the risk of burnout of the first metal layer M1 due to the local heat generation. Moreover, the problem of the stability characteristics of the transistors in the display panel can be taken into consideration comprehensively, and the second connection line 32 and the third connection line 33 can be arranged to avoid the transistors below, avoiding the characteristics of the transistors from being affected.

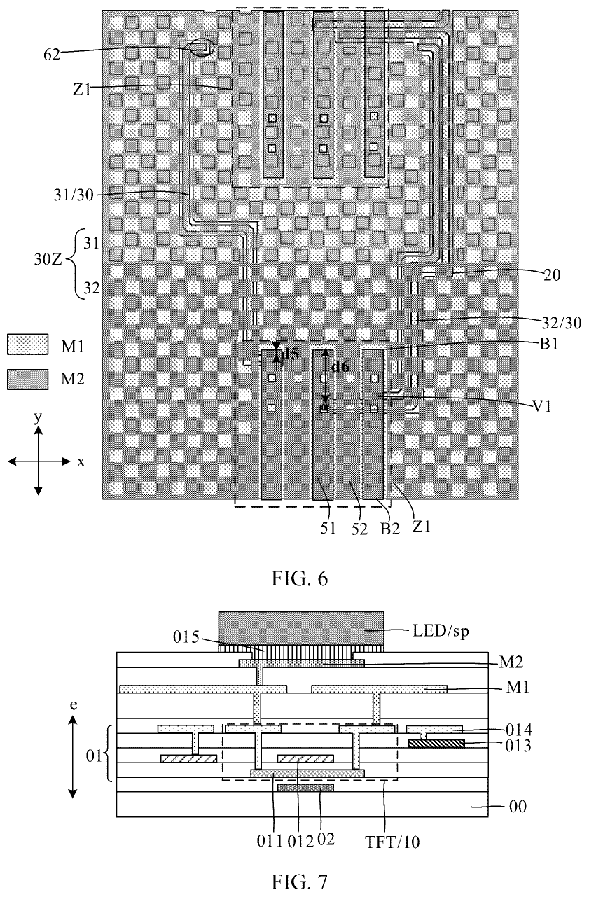

In some embodiments, FIG. 8 is a partial schematic diagram of another display panel provided by an embodiment of the present disclosure. FIG. 8 shows a partial position of the first metal layer M1 and a first edge Y1 of the display panel extending along the first direction x. The first edge Y1 can be understood in conjunction with FIG. 1A. As shown in FIG. 8, the connection-line groups 30Z includes a third connection-line group 30Z3 and a fourth connection-line group 30Z4. A distance between the third connection-line group 30Z3 and the first edge Y1 is less than a distance between the fourth connection-line group 30Z4 and the first edge Y1. In the third connection-line group 30Z3, the first end 61 of the first connection line 31 and the first end 61 of the third connection line 33 are staggered in the first direction x, and in the fourth connection-line group 30Z4, the first end 61 of the first connection line 31 and the first end 61 of the third connection line 33 are aligned in the first direction x. It is understood that in conjunction with FIG. 1B, the pixel circuit 10 or other circuit structures need to be disposed below the first metal layer M1, and the circuit is provided with a transistor structure, the channel of the transistor is easily affected by light, which will affect the performance of the transistor. In the embodiment of the present disclosure, the corresponding manner of the first end 61 of the first connection line 31 and the first end 61 of the third connection line 33 in the first direction x is designed to avoid the transistor structure below the first metal layer M1, preventing the slots 20 accommodating the electrode connection lines from exposing the transistor below, and ensuring the stability characteristics of the transistor.

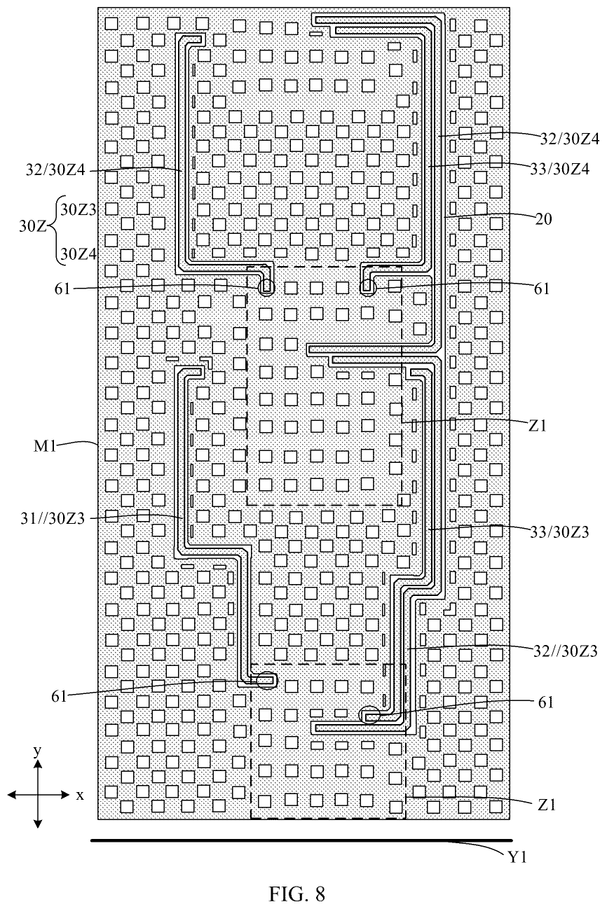

In some embodiments, FIG. 9 is a partial schematic diagram of another display panel provided by an embodiment of the present disclosure. FIG. 9 only illustrates an electrode connection-line group 30Z in simplified form. As shown in FIG. 9, the electrode connection line 30 includes a first line segment 30a extending along the second direction y, a second line segment 30b extending along the first direction x, and a third line segment 30c extending along the first direction x. Two ends of the first line segment 30a are connected to the second line segment 30b and the third line segment 30c. The second line segment 30b includes the first end 61 or the second line segment 30b is connected to the first end 61, and the third line segment 30c includes the second end 62 or the third line segment 30c is connected to the second end 62. It is illustrated in FIG. 9 that the second line segment 30b of the first connection line 31 is connected to an end extending along the second direction y, and this end is the first end 61. That is, in the first connection line 31, the second line segment 30b is connected to the first end 61. In the second connection line 32 and the third connection line 33, the second line segment 30b includes the first end 61. Correspondingly, it can be understood that in each of the three electrode connection lines, it is the third line segment 30c that includes the second end 62. A length of the second line segment 30b of the second connection line 32 in the first direction x is greater than a length of the second line segment 30b of the first connection line 31 in the first direction x, and/or, a length of the third line segment 30c of the second connection line 32 in the first direction x is greater than a length of the third line segment 30c of the first connection line 31 in the first direction x. As can be seen in conjunction with FIG. 1B that, in the embodiment of the present disclosure, the second connection line 32 is set to connect the middle one of the three sub-pixels sp in the pixel P, and the second connection line 32 is connected to the middle one of the three pixel circuits 10. Therefore, by reasonably designing the length of the line segment of each electrode connection line 30 according to the positions of the sub-pixels sp and the pixel circuits 10 connected by the electrode connection lines 30, the wiring manner in the display panel can be simplified, the routing can be reduced, and the layout space can be saved.

In some embodiments, as shown in FIG. 9, a distance between the first line segment 30a of the first connection line 31 and the first line segment 30a of the second connection line 32 is D1, in the first direction x, a distance between the first end of the first connection line 31 and the first end of the second connection line 32 is D2, and a distance between the second end of the first connection line 31 and the second end of the second connection line 32 is D3, where D1>D2, and D1>D3. In this embodiment, the first connection line 31 and the second connection line 32 form a curly-bracket-shaped wiring. The electrode connection lines forming a routing design can avoid the transistors between the first metal layer M1 and the substrate, to prevent the slots 20 on the first metal layer M1 accommodating the electrode connection lines from overlapping with the transistors, thereby preventing light from irradiating the transistors through the slots 20, and avoiding the change of the characteristics of the transistors after being subject to the light irradiation.

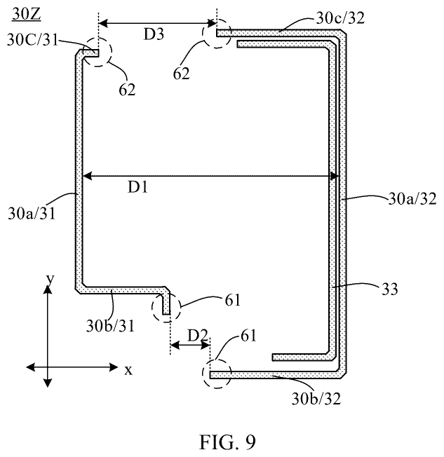

In some other embodiments, FIG. 10 is a simplified schematic diagram of another display panel provided by an embodiment of the present disclosure. FIG. 10 illustrates an electrode connection-line group 30Z, a group of pixel circuits 10, and the first electrodes 51 corresponding to three sub-pixels sp. As shown in FIG. 10, the first end 61 of each of the electrode connection lines 30 is connected to a first electrode 51, and the second end 62 of each of the electrode connection lines 30 is connected to a pixel circuit 10. The second end 62 of the first connection line 31 is connected to the foremost pixel circuit 10 among the three pixel circuits 10 arranged along the first direction x, and the first end 61 of the first connection line 31 is connected to the left-most first electrode 51 among the three first electrodes 51 arranged along the first direction x. The second end 62 of the second connection line 32 is connected to the middle pixel circuit 10 among the three pixel circuits 10 arranged along the first direction x, and the first end 61 of the second connection line 32 is connected to the middle first electrode 51 among the three first electrodes 51 arranged along the first direction x. The connection-line group 30Z further includes a third connection line 33. The second end 62 of the third connection line 33 is connected to the third pixel circuit 10 (counted from the left) among the three pixel circuits 10 arranged along the first direction x, and the first end 61 of the third connection line 33 is connected to the third first electrode 51 (counted from the left) among the three first electrodes 51 arranged along the first direction x. It can be seen that the distance between the first line segment 30a of the second connection line 32 and the first line segment 30a of the first connection line 31 is less than the distance between the first line segment 30a of the third connection line 33 and the first line segment 30a of the first connection line 31, that is, the second connection line 32 is routed on the inner side the third connection line 33. It can be seen from FIG. 10 that in the first direction x, the distance between the first end 61 of the third connection line 33 and the first end 61 of the first connection line 31 is greater than the distance between the first end 61 of the second connection line 32 and the first end 61 of the first connection line 31. In this embodiment, the slot where the second connection line 32 is located and the slot where the third connection line 33 is located are arranged to communicate with each other, the slot where the second connection line 32 is located and the slot where the first connection line 31 is located are arranged not to communicate with each other, and the first end 61 of the first connection line 31 and the first end 61 of the second connection line 32 are arranged to stagger in the first direction x.

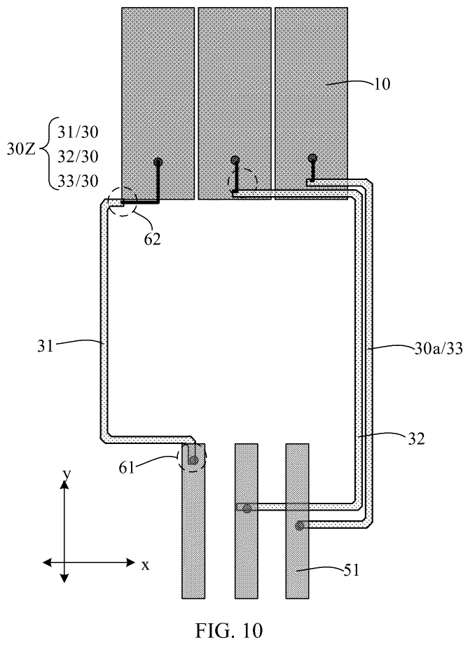

In some embodiments, FIG. 11A is a partial schematic diagram of another display panel provided by an embodiment of the present disclosure. As shown in FIG. 11A, the display panel includes a plurality of signal terminals 70. The signal terminals 70 are located on one side of the first metal layer M1 in the second direction y. The signal terminals 70 include a power-supply terminal 71. The first metal layer M1 is electrically connected to the power-supply terminal 71, and the power-supply terminal 71 provides signals to the first metal layer M1. In the connection-line group 30Z adjacent to the power-supply terminal 71, the first end 61 of the first connection line 31 and the first end 61 of the second connection line 32 are staggered in the first direction x. The first end 61 of each of the connection lines is circled in FIG. 11A. Since the connection-line group 30Z adjacent to the power-supply terminal 71 is closer to the power-supply source, the total current at its location is larger. Setting the two first ends 61 of the first connection line 31 and the second connection line 32 at this position to be staggered in the first direction x can improve the heat-generation problem in the region between the two first ends 61 at this position caused by a larger current, thereby reducing the risk of burnout of the region between the two first ends 61 and enhancing the performance reliability of the display panel.

In the embodiments of the present disclosure, the signal terminals 70 can be formed by stacking a plurality of metal sub-parts on the substrate 00. It is understood that in conjunction with the film-layer structure shown in FIG. 7, for example, the signal terminal 70 includes a sub-part located in the first metal layer M1, a sub-part located in the second metal layer M2, a sub-part located in the gate metal layer 012, and a sub-part located in the source-drain metal layer 014. Each sub-part overlaps and is electrically connected with each other in the direction e perpendicular to the substrate 00.

FIG. 11B is a schematic diagram of another display panel provided by an embodiment of the present disclosure. As shown in FIG. 11B, the signal terminals 70 are connected to side leads 701 of the display panel. The signal terminals 70 are used to connect the side leads 701 of the display panel to lead signals to the back of the display panel and then be bonded to a flexible circuit board, so as to reduce the bezel of the display panel and achieve a bezelless display effect.

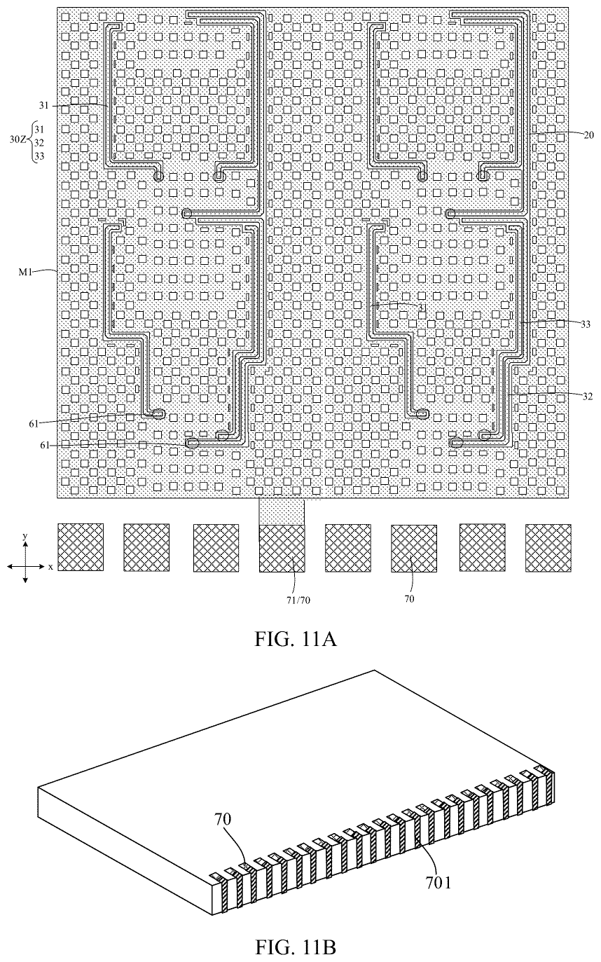

In some embodiments, FIG. 12 is a schematic diagram of another display panel provided by an embodiment of the present disclosure. FIG. 12 illustrates a partial position of the first metal layer M1 and a first edge Y1 of the display panel extending along the first direction x. The first edge Y1 can be understood in conjunction with FIG. 1A. It can be seen from FIG. 12 that in the connection-line group 30Z adjacent to the first edge Y1, the first end 61 of the first connection line 31 and the first end 61 of the second connection line 32 are staggered in the first direction x. In addition, as shown in FIG. 12, the connection-line groups 30Z include adjacent fifth and sixth connection-line groups 30Z5 and 30Z6. The fifth connection-line group 30Z5 is located on one side of the sixth connection-line group 30Z6 away from the first edge Y1. In the fifth connection-line group 30Z5, the first end 61 of the first connection line 31 and the first end 61 of the second connection line 32 are staggered in the first direction x. In this embodiment, the fifth connection-line group 30Z5 is not adjacent to the first edge Y1 and is closer to the inside of the display area than the sixth connection-line group 30Z6. In the embodiment of the present disclosure, first, the two first ends 61 of the first connection line 31 and the second connection line 32 in the sixth connection-line group 30Z6 adjacent to the first edge Y1 are arranged to be staggered in the first direction x, and further, the first end 61 of the first connection line 31 and the first end 61 of the second connection line 32 in the fifth connection-line group 30Z5 at a position far from the first edge Y1 are arranged to be staggered in the first direction x, which can not only improve the heat-generation problem in the region between the two first ends 61 caused by a larger current at the total current source of the first metal layer M1, but also further improve the problem of severe local heat generation in the site of the first metal layer M1 far from the first edge Y1.

As shown in FIG. 12, the first connection line 31 in the fifth connection-line group 30Z5 and the first connection line 31 in the sixth connection-line group 30Z6 are arranged along the second direction y. The slot 20 where the first connection line 31 in the fifth connection-line group 30Z5 is located and the slot 20 where the first connection line 31 in the sixth connection-line group 30Z6 is located are arranged along the second direction y and do not communicate with each other. In this embodiment, by setting the slots 20 where two adjacent first connection lines 31 in the second direction y are located not communicating with each other, an opening is formed between the two first connection lines 31. The opening is understood to mean that there is a solid metal structure of the first metal layer M1 at this position. A transverse current branch (as illustrated by the horizontal arrow in FIG. 12) can be formed at the position of the opening. In this way, on the first metal layer M1, there is not only a longitudinal power-supply path (illustrated by the vertical arrow) between two adjacent electrode connection lines 30 in the first direction x, but also the transverse current branch, which can reduce the risk of the first metal layer M1 being locally burned out due to excessive current and improve the performance reliability.

In some embodiments, as shown in FIG. 12, the first end 61 of the first connection line 31 and the first end 61 of the second connection line 32 in the fifth connection-line group 30Z5 are staggered in the first direction x. A virtual line extending along the first direction x is illustrated by a dotted line in FIG. 12. It can be seen that in the sixth connection-line group 30Z6, the second end 62 of the first connection line 31 is located below the virtual line, and the second end 62 of the second connection line 32 is located above the virtual line. That is, in the sixth connection-line group 30Z6, the second end 62 of the first connection line 31 and the second end 62 of the second connection line 32 are staggered in the first direction x. Such an arrangement can make the opening formed between the first connection line 31 in the fifth connection-line group 30Z5 and the first connection line 31 in the sixth connection-line group 30Z6 have a larger width in the second direction y, which can improve the current-transmission ability of the transverse current branch at the position of the opening and further reduce the risk of the first metal layer M1 being burned out due to excessive current.

In some embodiments, a plurality of connection-line groups 30Z are arranged along the second direction y to form a connection-line-group column. In the connection-line group 30Z, the second end 62 of the first connection line 31 and the second end 62 of the second connection line 32 are staggered in the first direction x, and along an arrangement direction of the plurality of connection-line groups 30Z, a staggering distance between the two second ends 62 in the first direction x gradually changes. Such an arrangement can cooperate with the design of the two first ends 61 of the first connection line 31 and the second connection line 32 in the connection-line group 30Z being staggered, so that an opening with an appropriate size is formed between two connection-line groups 30Z adjacent in the second direction y.

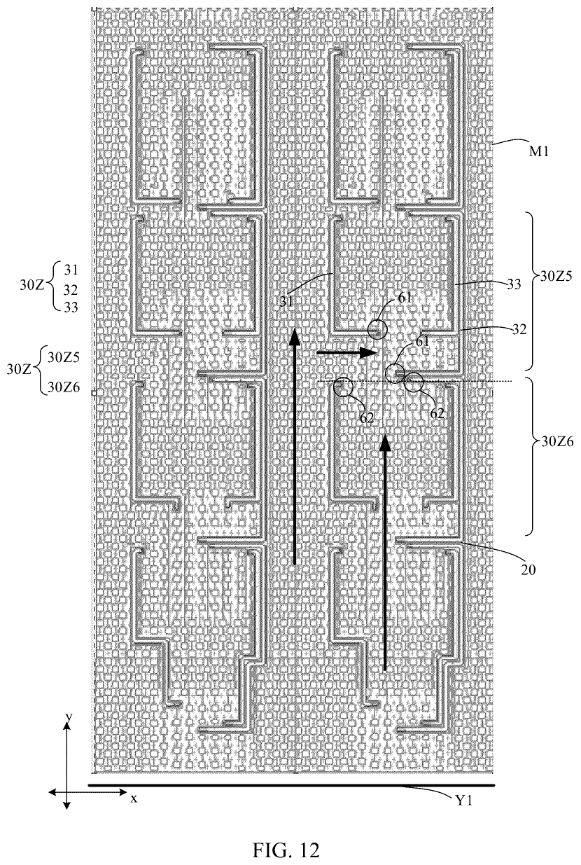

In some embodiments, FIG. 13 is a schematic diagram of another display panel provided by an embodiment of the present disclosure. FIG. 13 illustrates a connection relationship between the electrode connection line 30, the pixel circuit 10, and the sub-pixel sp. The electrode connection line 30 is connected to the sub-pixel sp through the first electrode 51. The sub-pixel sp includes a light-emitting diode. In FIG. 13, a red light-emitting diode RLED, a green light-emitting diode GLED, and a blue light-emitting diode BLED are illustrated. As shown in FIG. 13, the display panel includes a first edge Y1 extending along the first direction x. The sub-pixel sp includes a first sub-pixel 1sp, and the pixel circuit 10 includes a first pixel circuit 11. The first sub-pixel 1sp is connected to the first pixel circuit 11 through the electrode connection line 30, and the second end of the electrode connection line 30 is located on one side of its first end away from the first edge Y1. It can be seen that along the second direction y, a distance between the first pixel circuit 11 and the first edge Y1 is greater than a distance between the first sub-pixel 1sp and the first edge Y1. In FIG. 13, it is illustrated that three electrode connection lines 30 form one connection-line group 30Z. The pixel circuit 10 and the sub-pixel sp connected to the electrode connection line 30 are staggered in the first direction x. The pixel circuit 10 is shifted toward the inside of the display area relative to the sub-pixel sp. That is, the pixel circuit 10 is arranged to be retracted relative to the first edge Y1. Such an arrangement can narrow the bezel of the display panel.

A plurality of connection-line groups 30Z are arranged along the second direction y to form a connection-line-group column (not shown in FIG. 13). In FIG. 13, it is exemplified that the connection-line-group column includes four connection-line groups 30Z, which can be designed according to specific requirements in practice. As illustrated in FIG. 13, the display area includes a first display area AA1 and a second display area AA2, and the electrode connection line 30 is located in the first display area AA1. In the first display area AA1, the pixel circuit 10 and the first electrode 51 in the sub-pixel sp connected to it do not overlap, and thus the pixel circuit 1 and the first electrode 51 need to be connected through the electrode connection line 30. In the second display area AA2, the pixel circuit 10 and the first electrode 51 in the sub-pixel sp connected to it overlap, and there is no need to provide the electrode connection line defined by the present disclosure between the pixel circuit 1 and the first electrode 51. Therefore, it can be understood that in the embodiments of the present disclosure, the connection-line-group column does not correspond to a whole column of pixels arranged along the second direction y. The connection manner between the pixel circuit and the sub-pixel connected to it in the position close to the center area of the display area, such as in the second display area AA2, will be described in the following related embodiments.

As shown in FIG. 1A, the display panel includes a first edge Y1 extending along the first direction x and a second edge Y2 extending along the second direction y. At a position close to the first edge Y1, the pixel circuits 10 are shifted toward the inside of the display panel along the second direction y. It can be seen that the row of pixels P adjacent to the first edge Y1 does not overlap with the pixel circuits 10. Such an arrangement can reduce the width of the bezel of the display panel extending along the first direction x. At the same time, at a position close to the second edge Y2, some pixel circuits 10 are shifted toward the inside of the display panel along the first direction x. That is, the pixel circuits 10 are retracted inwards relative to the second edge Y2. It can be seen that the column of pixels P adjacent to the second edge Y2 does not overlap with the pixel circuits 10. Such an arrangement can reduce the width of the bezel of the display panel extending along the second direction y.

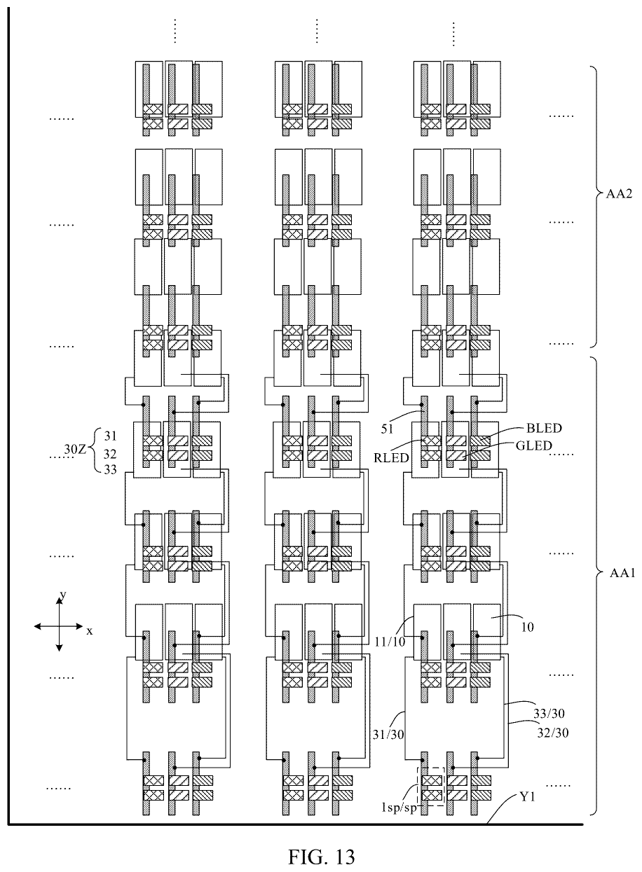

In some embodiments, FIG. 14 is a partial schematic diagram of another display panel provided by an embodiment of the present disclosure. FIG. 14 only illustrates a partial position of the first metal layer M1. As shown in FIG. 14, a plurality of connection-line groups 30Z are arranged along the second direction y to form a connection-line-group column 30ZL. FIG. 14 illustrates three connection-line groups 30Z in one connection-line-group column 30ZL. In the connection-line-group column 30ZL, the first connection lines 31 of adjacent connection-line groups 30Z are arranged along the second direction y. There are at least two connection-line groups 30Z, the two connection-line groups 30Z are adjacent in the second direction y, and the two slots 20 where the two first connection lines 31 of the two connection-line groups 30Z are located do not communicate with each other. In the embodiment of the present disclosure, by setting the two slots 20 where at least two adjacent first connection lines 31 in the connection-line-group column 30ZL are located not to communicate with each other, an opening can be formed between the two adjacent first connection lines 31, and a transverse current branch (indicated by an arrow) can be formed at the position of the opening. On the first metal layer M1, there is not only a longitudinal power-supply path (indicated by an arrow) between the adjacent electrode connection lines 30 in the first direction x, but also a transverse current branch formed, which can reduce the risk of the first metal layer M1 being burned out due to excessive current and improve the performance reliability.

In some embodiments, as shown in FIG. 14, in the connection-line-group column 30ZL, the two slots 20 where two first connection lines 31 of any two adjacent connection-line groups 30Z are located do not communicate with each other. Such an arrangement makes more transverse current branches formed on the connection-line-group column 30ZL, which is more conducive to dispersing the current in the first metal layer M1 and reducing the risk of the first metal layer M1 being burned out locally due to excessive current.

In some embodiments, as shown in FIG. 14, the display panel includes a pixel region Z1 and a non-pixel region Z2. The region outside the pixel region Z1 is the non-pixel region Z2. A part of the first metal layer M1 located in the pixel region Z1 includes a plurality of first vent holes 41, and a part of the first metal layer M1 located in the non-pixel region Z2 includes a plurality of second vent holes 42. The second vent holes 42 are arranged along the first direction x to form second vent-hole rows 42H. The second vent holes 42 are used as gas-discharge channels during the manufacturing process, which can prevent the large-area first metal layer M1 from film-peeling due to the fact that the gas cannot be discharged. It can be seen from a region Q3 in FIG. 14 that the two slots 20 where the two first connection lines 31 of at least two adjacent connection-line groups 30Z among the connection-line groups 30Z are located are separated by at least one second vent-hole row 42H along the second direction y. In this embodiment, the region between the slot 20 and the second vent hole 42 is the solid metal of the first metal layer M1, which can serve as a transverse current branch to reduce the risk of the first metal layer M1 being burned out locally due to excessive current.

In some embodiments, as shown in FIG. 14, a distance between two adjacent second vent holes 42 in the second direction y is d7. Two adjacent second vent holes 42 in the second direction y means that the two second vent holes 42 are basically located on a same straight line extending along the second direction y. It can be seen from the position of the region Q4 that in the connection-line groups 30Z, a minimum distance along the second direction y between the two slots 20 where the two first connection lines 31 of at least two adjacent connection-line groups 30Z are located is d8, where d8≥d7. The region between two adjacent second vent holes 42 in the second direction y is the solid metal of the first metal layer M1. In this embodiment, it is set that d8≥d7, so that a transverse current branch can be formed in the region between two adjacent slots 20 in the second direction y to reduce the risk of the first metal layer M1 being burned out due to excessive current.

In some embodiments, as shown in FIG. 14, the connection-line-group column 30Z includes a first connection-line-group column 30Z1 and a second connection-line-group column 30Z2. The arrangement manner of the electrode connection lines 30 in the first connection-line-group column 30Z1 and the arrangement manner of the electrode connection lines 30 in the second connection-line-group column 30Z2 are the same. This implementation uses the same wiring design for each connection-line-group column 30Z, simplifying the design rule of the slots 20 in the first metal layer M1.

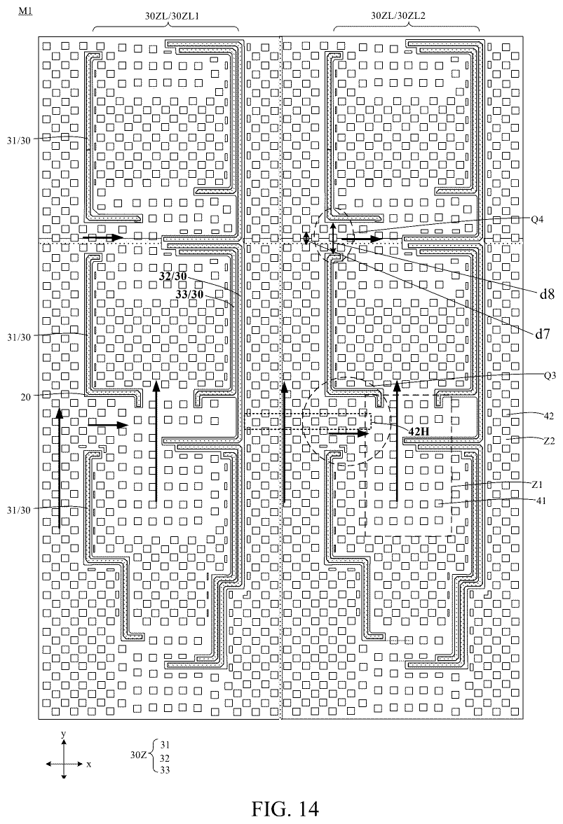

In some embodiments, FIG. 15 is a partial simplified schematic diagram of another display panel provided by an embodiment of the present disclosure. In FIG. 15, only the slots 20 in the first metal layer M1 and the electrode connection lines 30 located in the slots 20 are illustrated. As shown in FIG. 15, in the connection-line-group column 30ZL, a minimum distance along the second direction y between two slots 20 where two adjacent first connection lines 31 are located gradually changes. Combining with FIG. 13, it can be understood that the number of connection-line groups in the connection-line-group column 30ZL is less than the number of pixels in a whole column of pixels arranged along the second direction y. That is, the electrode connection lines 30 are basically arranged on both sides of the display panel in the second direction y. At the position where no electrode connection line 30 is disposed, no slot 20 needs to be disposed on the first metal layer. The arrangement that in the connection-line-group column 30ZL the minimum distance between two slots 20 where two adjacent first connection lines 31 are located in the second direction y gradually changes can balance the resistance differences at different positions on the first metal layer, so that the signal-transmission ability of the transverse current branch gradually changes, and the risk of the first metal layer M1 being burned out locally due to excessive current is reduced.

In some embodiments, as shown in FIG. 15, the display panel includes a first edge Y1 extending along the first direction x. A plurality of signal terminals 70 are disposed between the first edge Y1 and the first metal layer (not shown in FIG. 15), that is, the signal terminals 70 are disposed on one side of the first metal layer M1 in the second direction y, and the signal terminals 70 are located on the side of the first metal layer M1 close to the first edge Y1. The signal terminals 70 include a power-supply terminal 71. In conjunction with FIG. 11A, the first metal layer M1 is electrically connected to the power-supply terminal 71. Along the second direction y away from the first edge Y1, in the connection-line-group column 30ZL, the minimum distance along the second direction y between two slots 20 where two adjacent first connection lines 31 are located gradually decreases. In the embodiment of the present disclosure, the power-supply terminal 71 is disposed near the first edge Y1, the total current at the position on the first metal layer close to the power-supply terminal 71 is larger, and the risk of the first metal layer being burned out is also relatively higher. By using the design of this embodiment of the present disclosure, along the second direction y away from the first edge Y1, a width of an opening formed by two adjacent first connection lines 31 in the connection-line-group column 30ZL gradually decreases. A larger transverse current branch can be formed by using a larger-width opening at the position near the first edge Y1 to reduce the risk of the first metal layer M1 being burned out locally due to excessive current. At a position far from the first edge Y1, a smaller-width opening is used for the transition of the transverse current branch to achieve a relatively stable transition of the current on the first metal layer between the region where the electrode connection lines 30 are located and the region where on electrode connection lines 30 is located.

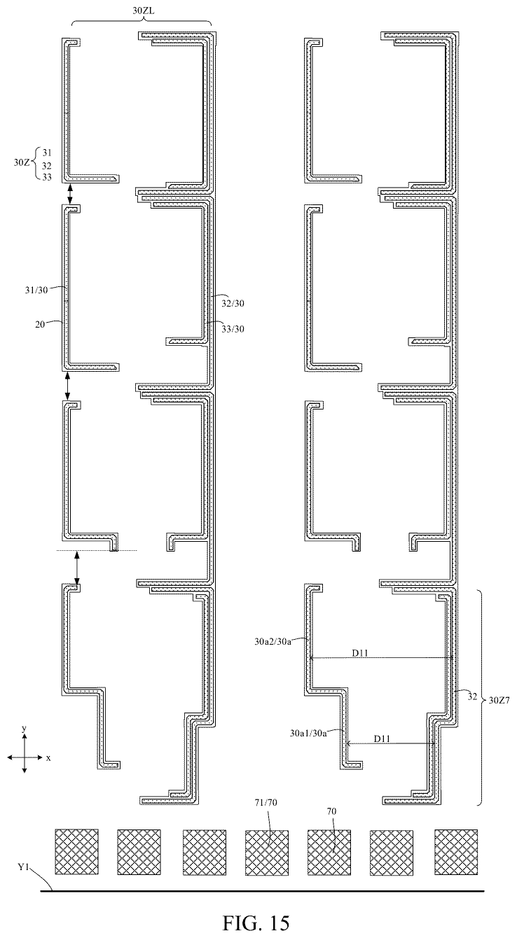

In some embodiments, FIG. 16 is a partial schematic diagram of another display panel provided by an embodiment of the present disclosure. FIG. 16 is a simplified schematic diagram, and only shows the wiring situation of the electrode connection lines 30. As shown in FIG. 16, in the connection-line-group column 30ZL, the second connection lines 32 of adjacent connection-line groups 30Z are arranged along the second direction y. There are at least two connection-line groups 30Z, the at least two connection-line groups 30Z are adjacent, and the slots 20 where the two second connection lines 32 of the two connection-line groups 30Z are located do not communicate with each other. As can be seen from the position of the region Q5, the slots 20 where the two second connection lines 32 of two adjacent connection-line groups 30Z in the second direction y do not communicate with each other. It is understood in conjunction with the first metal layer M1 illustrated in FIG. 1B that if the two slots 20 where the two second connection lines 32 are located do not communicate with each other, it is possible to enable the existence of a solid metal structure of the first metal layer M1 between the two slots 20 where the two adjacent second connection lines 32 in the second direction y are located, and the solid metal structure of the first metal layer M1 forms a transverse current branch. Such an arrangement can form more transverse power-supply branches between the adjacent electrode connection lines 30 in the second direction y, which is more conducive to reducing the risk of the first metal layer M1 being burned out locally due to excessive current.

In some embodiments, in the connection-line-group column 30ZL, the slots 20 where the second connection lines 32 of any two adjacent connection-line groups 30Z are located do not communicate with each other, which is no longer illustrated in the accompanying drawings here.

In some embodiments, as shown in FIG. 15, the display panel includes a first edge Y1 extending along the first direction x, and the connection-line groups 30Z includes a seventh connection-line group 30Z7. The seventh connection-line group 30Z7 is adjacent to the first edge Y1, and at least one electrode connection line 30 in the seventh connection-line group 30Z7 includes two first line segments 30a extending along the second direction y. The first connection line 31 in the seventh connection-line group 30Z7 includes two first line segments 30a, which are a first line sub-segment 30a1 and a second line sub-segment 30a2. In the first direction x, a distance between the first line sub-segment 30a1 and the second connection line 32 is D11, and a distance between the second line sub-segment 30a2 and the second connection line 32 is D12, where D11<D12. The first line sub-segment 30a1 is on one side of the second line sub-segment 30a2 close to the first edge Y1. In this embodiment, the first line sub-segment 30a1 and the second line sub-segment 30a2 form a stepped trace. In practical applications, a circuit structure such as an electrostatic discharge protection circuit can be arranged between the first sub-line segment 30a1 and the second connection line 32. The first line sub-segment 30a1 and the second connection line 32 are routed on the left and right sides of the electrostatic discharge protection circuit respectively, so that the first line sub-segment 30a1 and the second connection line 32 do not overlap with the transistors in the electrostatic discharge protection circuit, which can prevent light from irradiating the transistors through the slots 20 on the first metal layer M1 and avoid the change of characteristics of the transistors caused by light.

In some embodiments, as shown in FIG. 13, the display panel includes a first display area AA1 and a second display area AA2, and the electrode connection lines 30 are located in the first display area AA1. FIG. 2 illustrates a partial schematic diagram of the first display area AA1. It can be seen from FIG. 2 that the display panel includes a pixel region Z1 and a non-pixel region Z2. The region outside the pixel region Z1 is the non-pixel region Z2. The pixels P are located in the pixel region Z1. In the first display area AA1, the first metal layer M1 located in the pixel region Z1 includes a plurality of first vent holes 41, and the first metal layer M1 located in the non-pixel region Z2 includes a plurality of second vent holes 42. The arrangement manner of the first vent holes 41 is different from the arrangement manner of the second vent holes 42. Designing the arrangement manner of the vent holes differently in conjunction with the positions of different metal parts in the first metal layer M1 can help venting of gases during the process and prevent the first metal layer M1 from film-peeling.

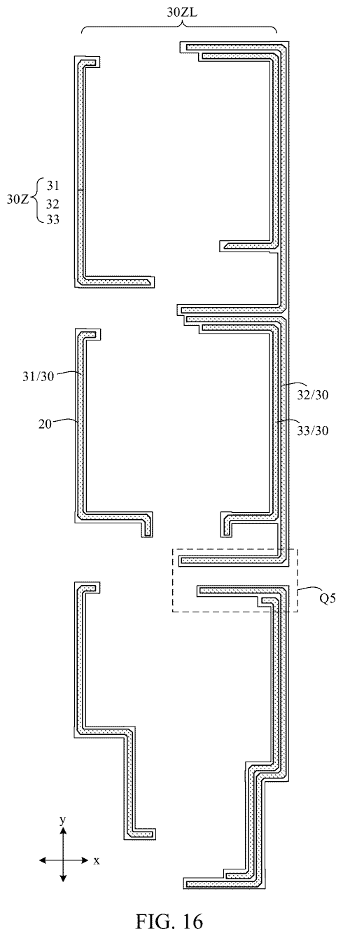

FIG. 17 is a partial schematic diagram of another display panel provided by an embodiment of the present disclosure, and FIG. 17 illustrates a partial view of the first metal layer M1 in the second display area AA2. As shown in FIG. 17, in the second display area AA2, the first metal layer M1 located in the pixel region Z1 includes a plurality of first vent holes 41, the first metal layer M1 located in the non-pixel region Z2 includes a plurality of second vent holes 42 and a plurality of third vent holes 43, the area of the third vent hole 43 is larger than the area of the first vent hole 41 and larger than the area of the second vent hole 42. The arrangement manner of the first vent holes 41 in the pixel region Z1 of the first display area AA1 is approximately the same as the arrangement manner of the first vent holes 41 in the pixel region Z1 of the second display area AA2. Due to the influence of the manufacturing process of the metal layer, the overall area of the metal layer is limited, and in the second display area AA2, the first metal layer M1 is further provided with the third vent hole 43 with a larger area size, so that the metal area of the first metal layer M1 is reduced and the process yield is ensured.

In addition, in FIG. 17, a connection electrode 54 is shown in the pixel region Z1. There is a slot (not shown in FIG. 17) on the first metal layer M1 located in the pixel region Z1, and the connection electrode 54 is located in the slot. The connection electrode 54 is connected between the pixel circuit and the sub-pixel. In the second display area AA2, the pixel circuit and its corresponding sub-pixel overlap in the direction perpendicular to the plane of the substrate. The connection electrode 54 is connected to the pixel circuit through the via-hole below it and connected to the first electrode (shown in FIG. 13) through the via-hole above it, and then connected to the sub-pixel.

Based on the same inventive concept, an embodiment of the present disclosure further provide a display device. The display device includes a display panel provided by any one of the embodiments of the present disclosure. The structure of the display panel has been described in the above-mentioned embodiments, and will not be repeated here. The display device provided by the embodiment of the present disclosure can be, for example, an electronic device with a display function, such as a mobile phone, a tablet, a computer, a television, or a smart wearable product and the like. The display device provided by the embodiment of the present disclosure can also be a transparent display device, such as a transparent display window, or a spliced display device, such as a large-screen for a conference room, an exhibition hall and the like.

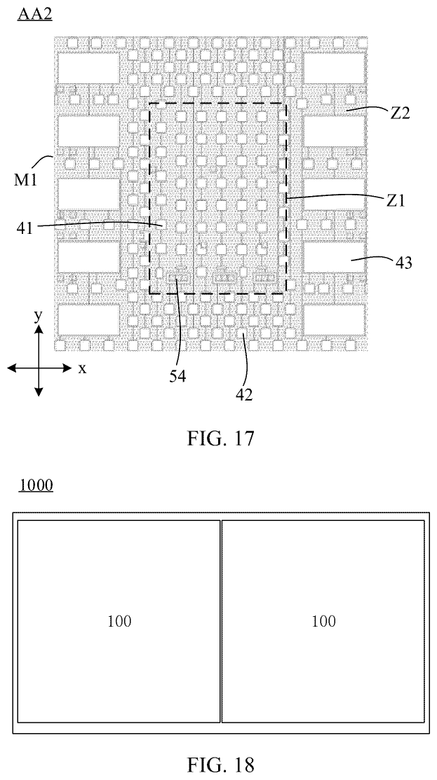

In one embodiment, FIG. 18 is a schematic diagram of a display device provided by an embodiment of the present disclosure. As shown in FIG. 18, the display device 1000 includes two display panels 100 that are spliced with each other. The display panel 100 is one provided by any one of the embodiments of the present disclosure. The spliced display device provided by the embodiment of the present disclosure includes a total of a×b display panels arranged in a rows and b columns. Both a and b are positive integers, and a and b are not 1 at the same time.

Finally, it should be noted that the above embodiments are only used to illustrate the technical solutions of the present disclosure, not to limit them. Although the present disclosure has been described in detail with reference to the above-mentioned embodiments, those of skill in the art should understand that they can still modify the technical solutions recited in the above-mentioned embodiments, or replace some or all of the technical features with equivalent ones. However, these modifications or replacements do not make the essence of the corresponding technical solutions deviate from the scope of the technical solutions of the embodiments of the present disclosure.

What is claimed is:

1. A display panel, comprising a first metal layer, a plurality of sub-pixels, and a plurality of pixel circuits;
wherein at least two sub-pixels arranged along a first direction form a pixel; the first metal layer has slots provided with electrode connection lines, and the electrode connection lines and the first metal layer are located in a same layer; the electrode connection lines respectively comprise a first end connected to one of the sub-pixels, a second end connected to one of the pixel circuits, and a first line segment extending along a second direction, the first end and the second end are located on both sides of the first line segment in the second direction, and the second direction intersects the first direction;
the electrode connection lines connected to the sub-pixels in a same pixel form a connection-line group; the electrode connection lines in the connection-line group comprise a first connection line and a second connection line, and the first connection line and the second connection line are located in different slots; and in the first direction, the first line segment of the first connection line and the first line segment of the second connection line are located on both sides of the pixel; and
in at least one connection-line group, the first end of the first connection line and the first end of the second connection line are staggered in the first direction.

2. The display panel according to claim 1, further comprising a pixel region, wherein the pixel is located in the pixel region; a part of the first metal layer located in the pixel region comprises a plurality of first vent holes; and in the pixel region, the first vent holes are arranged along the first direction to form first vent-hole rows; and
in at least one connection-line group, the first end of the first connection line and the first end of the second connection line are separated along the second direction by at least one first vent-hole row.

3. The display panel according to claim 1, further comprising a pixel region, wherein, the pixels are located in the pixel region; a part of the first metal layer located in the pixel region comprises a plurality of first vent holes; in the pixel region, the first vent holes are arranged along the first direction to form first vent-hole rows;
in the second direction, a distance between two adjacent first vent-hole rows is d1; and
in at least one connection-line group, a minimum distance along the second direction between the slot where the first connection line is located and the slot where the second connection line is located is d2, and d2≥d1.

4. The display panel according to claim 1, further comprising a pixel region, wherein the pixels are located in the pixel region; a part of the first metal layer located in the pixel region comprises a plurality of first vent holes; and in the pixel region, the first vent holes are arranged along the first direction to form first vent-hole rows; and
in at least one connection-line group, the first end of the first connection line overlaps along the first direction with one of the first vent-hole rows, the first end of the second connection line overlaps along the first direction with another one of the first vent-hole rows, and the first vent-hole row overlapping with the first connection line is adjacent to the first vent-hole row overlapping with the second connection line.

5. The display panel according to claim 1, further comprising a first edge extending along the first direction;
wherein a plurality of connection-line groups comprise a first connection-line group and a second connection-line group, and a distance between the first connection-line group and the first edge is less than a distance between the second connection-line group and the first edge;
in the first connection-line group, the first end of the first connection line and the first end of the second connection line are staggered in the first direction, and a staggering distance between the two along the second direction is d3; and
in the second connection-line group, the first end of the first connection line and the first end of the second connection line are staggered in the first direction, and a staggering distance between the two along the second direction is d4, and d4<d3.

6. The display panel according to claim 1, further comprising first electrodes and second electrodes, wherein the first electrodes and the second electrodes are located in a same layer; a film layer where the first electrodes and the second electrodes are located is placed between the first metal layer and the plurality of sub-pixels, and the sub-pixels are correspondingly connected to the first electrodes and the second electrodes; and the electrode connection lines are correspondingly connected to the sub-pixels through the first electrodes;
the first electrodes respectively comprise a first side and a second side opposite to each other in the second direction; and
along the second direction, a distance between the first end of the first connection line and the first side is d5, and a distance between the first end of the second connection line and the first side is d6, and d5≠d6.

7. The display panel according to claim 1, wherein the electrode connection lines in the connection-line group further comprise a third connection line, and the slot where the third connection line is located communicates with the slot where the second connection line is located; and
in at least one connection-line group, the first end of the first connection line and the first end of the third connection line are staggered in the first direction, or the first end of the first connection line and the first end of the third connection line are aligned in the first direction.

8. The display panel according to claim 7, further comprising a first edge extending along the first direction;
wherein a plurality of connection-line groups comprise a third connection-line group and a fourth connection-line group, and a distance between the third connection-line group and the first edge is less than a distance between the fourth connection-line group and the first edge; and
in the third connection-line group, the first end of the first connection line and the first end of the third connection line are staggered in the first direction; and in the fourth connection-line group, the first end of the first connection line and the first end of the third connection line are aligned in the first direction.

9. The display panel according to claim 7, wherein three sub-pixels arranged along the first direction form a pixel; and
in the pixel, the sub-pixel connected to the first connection line, the sub-pixel connected to the second connection line, and the sub-pixel connected to the third connection line are arranged in sequence.

10. The display panel according to claim 1, wherein the electrode connection lines respectively comprise a second line segment extending along the first direction and a third line segment extending along the first direction, and two ends of the first line segment are connected to the second line segment and the third line segment;
the second line segment comprises the first end or the second line segment is connected to the first end; and the third line segment comprises the second end or the third line segment is connected to the second end; and
wherein a length of the second line segment of the second connection line in the first direction is greater than a length of the second line segment of the first connection line in the first direction; and/or
a length of the third line segment of the second connection line in the first direction is greater than a length of the third line segment of the first connection line in the first direction.

11. The display panel according to claim 1, further comprising a power-supply terminal;
wherein in the connection-line group adjacent to the power-supply terminal, the first end of the first connection line and the first end of the second connection line are staggered in the first direction.

12. The display panel according to claim 1, further comprising a first edge extending along the first direction;
wherein a plurality of the connection-line groups comprise a fifth connection-line group and a sixth connection-line group that are adjacent to each other; the fifth connection-line group is located on one side of the sixth connection-line group away from the first edge; and in the fifth connection-line group, the first end of the first connection line and the first end of the second connection line are staggered in the first direction.

13. The display panel according to claim 12, wherein the first connection line in the fifth connection-line group and the first connection line in the sixth connection-line group are arranged along the second direction; and
the slot where the first connection line in the fifth connection-line group is located and the slot where the first connection line in the sixth connection-line group is located are arranged along the second direction and do not communicate with each other.

14. The display panel according to claim 13, wherein in the sixth connection-line group, the second end of the first connection line and the second end of the second connection line are staggered in the first direction.

15. The display panel according to claim 1, wherein a plurality of connection-line groups are arranged along the second direction to form a connection-line-group column; and
in the connection-line-group column, the first connection lines of adjacent connection-line groups are arranged along the second direction, at least two connection-line groups are provided, and the two connection-line groups are adjacent in the second direction, and the two slots where the two first connection lines of the two connection-line groups are located do not communicate with each other.

16. The display panel according to claim 15, wherein in the connection-line-group column, the two slots where the two first connection lines of any two adjacent connection-line groups are located do not communicate with each other.

17. The display panel according to claim 16, wherein in the connection-line-group column, a minimum distance along the second direction between the two slots where two adjacent first connection lines are located gradually changes.

18. The display panel according to claim 17, further comprising a first edge extending along the first direction;
wherein along the second direction away from the first edge, the minimum distance along the second direction between the two slots where two adjacent first connection lines in the connection-line-group column are located gradually decreases.

19. The display panel according to claim 15, wherein in the connection-line-group column, the second connection lines of two adjacent connection-line groups are arranged along the second direction, at least two connection-line groups are provided, and the two connection-line groups are adjacent, and the two slots where the two second connection lines of the two connection-line groups are located do not communicate with each other.

20. A display device, comprising a display panel, wherein the display panel comprises a first metal layer, a plurality of sub-pixels, and a plurality of pixel circuits;
wherein at least two sub-pixels arranged along a first direction form a pixel; the first metal layer has slots provided with electrode connection lines, and the electrode connection lines and the first metal layer are located in a same layer; the electrode connection lines respectively comprise a first end connected to one of the sub-pixels, a second end connected to one of the pixel circuits, and a first line segment extending along a second direction, the first end and the second end are located on both sides of the first line segment in the second direction, and the second direction intersects the first direction;
the electrode connection lines connected to the sub-pixels in a same pixel form a connection-line group; the electrode connection lines in the connection-line group comprise a first connection line and a second connection line, and the first connection line and the second connection line are located in different slots; and in the first direction, the first line segment of the first connection line and the first line segment of the second connection line are located on both sides of the pixel; and
in at least one connection-line group, the first end of the first connection line and the first end of the second connection line are staggered in the first direction.
